(19) United States
(12) Patent Application Publication
(10) Pub. No.: US 2014/0288871 A1
(43) Pub. Date: Sep. 25, 2014

(54) TEST APPARATUS AND TEST SYSTEM

(71) Applicant: KAUSHIKI KAISHIA TOSHIBA, Tokyo (JP)

(72) Inventors: Masayuki Shibaoka, Kanagawa (JP); Tsutomu Unesaki, Tokyo (JP)

(73) Assignee: KABUSHIKI KAISHA TOSHIBA, Tokyo (JP)

(21) Appl. No.: 13/960,003

(22) Filed: Aug. 6, 2013

(30) Foreign Application Priority Data
Mar. 22, 2013 (JP) 2013-060757

(51) Int. Cl. G01R 31/26

(52) U.S. Cl. CPC G01R 31/2601
USPC 702/118; 702/117

(57) ABSTRACT

A test apparatus of the present embodiment has a logic cell, a host and a first bus. The host includes: a conversion section configured to analyze a test vector and convert the test vector to signal control data and a waveform shape; and a judgment section configured to analyze an expected value comparison result to perform success/failure judgment of a test of a semiconductor circuit. The logic cell is provided with a first storage section configured to store the signal control data, a second storage section configured to store the waveform shape as a waveform shape table, a waveform generating section configured to generate an output waveform for controlling the semiconductor circuit and output the output waveform, and an expected value comparing section configured to obtain the expected value comparison result on the basis of the signal control data and the waveform shape table.

### CROSS-REFERENCE TO RELATED APPLICATION

This application is based upon and claims the benefit of priority from the prior Japanese Patent Application No.2013-60757 filed on Mar. 22, 2013; the entire contents of which are incorporated herein by reference.

### FIELD

An embodiment described herein relates generally to a test apparatus and a test system.

### BACKGROUND

Conventionally, an LSI tester is generally used when testing a large-scale semiconductor. The LSI tester is an apparatus which, by freely controlling a signal for a semiconductor integrated circuit to be tested (DUT), monitoring a signal state of the DUT and performing comparison with an expected value, verifies whether the DUT is correctly operating or not. In order to use the LSI tester, a test vector for causing the DUT to operate is required. In recent years, however, in which the scale of a semiconductor integrated circuit is increasing, the scale and the number of test vectors in which signal processing of a test target and an expected value are described are increasing due to increase in the number of test targets and test items, and a huge amount of labor is required to verify correctness of a test vector itself.

In order to verify a test vector, verification by simulation on a general-purpose computer or verification by an apparatus called a DFT tester whose function is limited to a logic test are often performed, in addition to verification by actual execution of the test vector on the LSI tester. This is because the LSI tester is very expensive and is of high utility value and, therefore, it is difficult to continue to use the LSI tester for a long time period only for the purpose of verification of a test vector.

However, there is a problem that the verification by simulation on a general-purpose computer requires a huge amount of time and is not suitable for verification of a lot of large-scale test vectors. The DFT tester is more inexpensive than the LSI tester but is not such an inexpensive apparatus that all test vector developers can always occupy. Furthermore, there is a problem that the executable scale of a test vector is restricted due to the functional restriction.

Furthermore, there is also an apparatus which, in order to perform a DC test in consideration of a logic test and a voltage fluctuation value more inexpensively, performs a DC test by connecting an FPGA and various analog circuits to a DUT.

However, there is a problem that it is impossible to develop such an apparatus for an LSI tester and use a test vector immediately as it is.

### BRIEF DESCRIPTION OF THE DRAWINGS

FIG. 1 is a block diagram showing a configuration of a test system having a test apparatus according to an embodiment;

FIG. 2 is a diagram for illustrating an example of signal control in the test system;

FIG. 3 is a diagram for illustrating a configuration of a signal control module 15 in an FPGA section 6;

FIG. 4 is a diagram showing a configuration of a circuit for realizing synchronous control among logic cells 8, 9 and 10;

FIG. 5 is a diagram showing an example of a timing chart at the time of controlling the circuit in FIG. 4;

FIG. 6 is a schematic diagram for illustrating the kinds of and transmission routes for data transmitted and received in a test system 1;

FIG. 7 is a diagram showing an example of a waveform shape table 16 held by each signal control module 15 in the FPGA section 6;

FIG. 8 is a diagram showing an example of symbols which can be written as waveform elements in the waveform shape table 16; and

FIG. 9 is a diagram showing a structure of signal control data 42 transferred from a host 5 to the FPGA section 6.

### DETAILED DESCRIPTION

A test apparatus of the present embodiment has a logic cell, a host and a first bus. The host is provided with a conversion section configured to analyze a test vector for performing a test of a semiconductor circuit and convert the test vector to signal control data and a waveform shape, and a judgment section configured to, by controlling the semiconductor circuit with the signal control data, analyze an expected value comparison result obtained from the logic cell to perform success/failure judgment of the test of the semiconductor circuit. The logic cell is provided with a first storage section configured to store the signal control data transmitted via the first bus, a second storage section configured to store the waveform shape transmitted via the first bus as a waveform shape table, a waveform generating section configured to generate an output waveform for controlling the semiconductor circuit on the basis of the signal control data and the waveform shape table and output the output waveform to the semiconductor circuit, and an expected value comparing section configured to generate an expected value on the basis of the signal control data and the waveform shape table and obtain the expected value comparison result in which a signal value inputted from the semiconductor circuit is compared with the expected value.

An embodiment of the present invention will be described in detail with reference to drawings.

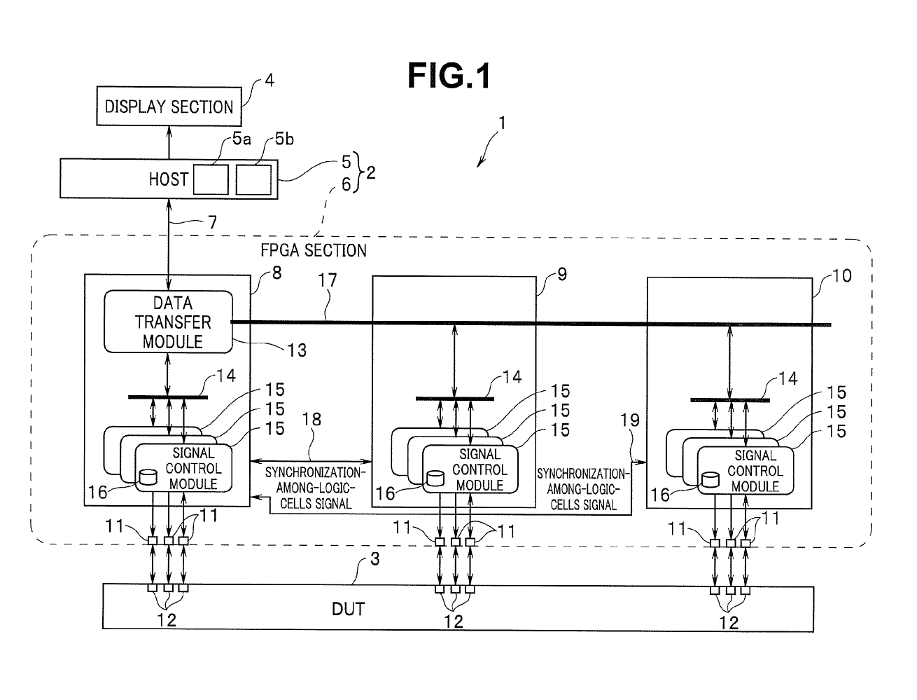

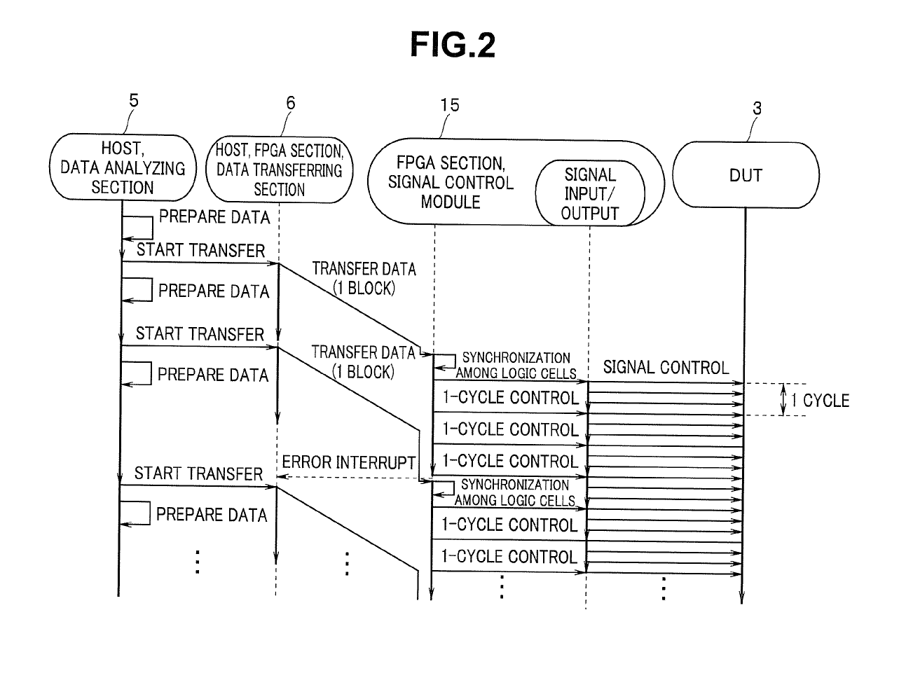

FIG. 1 is a block diagram showing a test system having a test apparatus according to the embodiment. FIG. 2 is a diagram for illustrating an example of signal control in the test system.

A test system 1 is configured having a test apparatus 2, a DUT 3 and a display section 4. The test apparatus 2 is configured having a host 5 and an FPGA section 6, and the host 5 and the FPGA section 6 are connected via a bus 7. The host 5 is configured having a conversion section 5a configured to analyze a test vector for performing a test of the DUT 3 and convert the test vector to signal control data and a waveform shape, and a judgment section 5b configured to analyze an expected value comparison result obtained from the FPGA section 6 by controlling the DUT 3 and perform success/failure judgment of the test. The host 5 displays a result of the success/failure judgment of the test performed by the judgment section 5b, on the display section 4.

In the present embodiment, STIL (Standard Test Interface Language) is used for a test vector, and a test vector created at another phase of LSI verification is directly used. The STIL is an industry-standard test pattern description language authorized as IEEE Std 1450.0-1999. The STIL is a standardized language, it can be used as a common language from testing/designing to failure analysis of an LSI, and it is not necessary to convert test data at each verification phase. Thus, there is a merit of performing verification work of the LSI seamlessly.

The FPGA section 6 is configured having a plurality of logic cells (here, a first logic cell 8, a second logic cell 9 and a third logic cell 10) and a plurality of input/output terminals 11. Note that the number of logic cells of the FPGA section 6 is not limited to three, and the FPGA section 6 is only required to have one or more logic cells. Note that the test apparatus 2 may be adapted to perform a DC test by connecting an analog circuit to a part of the plurality of input/output terminals 11.

The DUT 3 is one or more semiconductor integrated circuits to be tested and has a plurality of input/output terminals 12 to be controlled. The plurality of input/output terminals 12 are one-to-one connected to the plurality of input/output terminals 11 of the FPGA section 6, respectively.

The test apparatus 2 causes the DUT 3 to operate by causing the input/output terminals 11 just as described in a test vector, and obtains a signal value from the input/output terminals 12, from the input/output terminals 11. Then, by comparing the signal value obtained from the DUT 3 with an expected value of the test vector, the test apparatus 2 performs success/failure judgment of testing of the DUT 3. At this time, the FPGA section 6 controls the DUT 3 in accordance with a waveform defined in the test vector by dividing one cycle for the DUT 3 into a plurality of cycles (in the example of FIG. 2, three cycles) and performing control. More specifically, the FPGA section 6 outputs signal control data for testing the DUT 3.

The host 5 is a general-purpose computer for testing the DUT 3 by performing analysis and conversion of a test vector and controlling the FPGA section 6 on the basis of the analysis and the conversion. First, the host 5 analyses a test vector to be an input, generates a set of signal control data and outputs it to the first logic cell 8 via the bus 7.

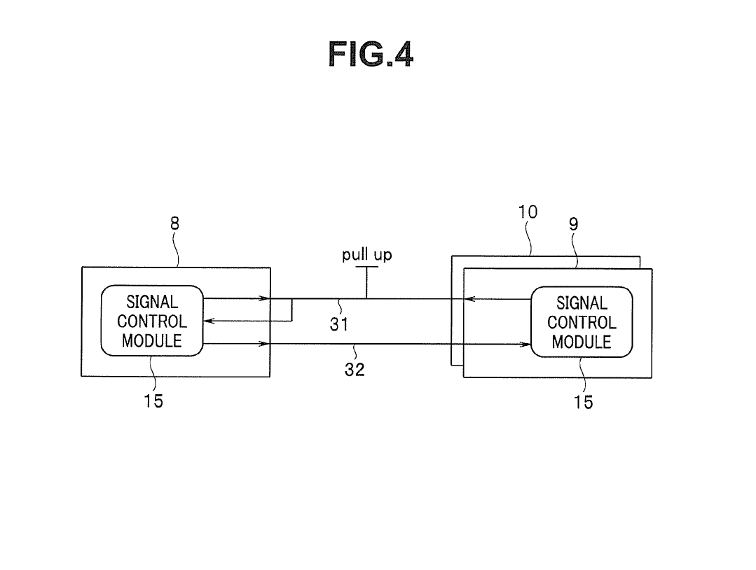

Each of the first to third cells 8 to 10 is configured having a bus 14, a plurality of signal control modules 15, and a waveform shape table 16. The first logic cell 8 has a data transfer module 13. Furthermore, the first to third logic cells 8 to 10 are connected via a bus 17. Furthermore, the first to third logic cells 8 to 10 are connected via synchronization signal lines 18 and 19. Here, it is simply described that logic cells are one-to-one connected with two signal lines. An implementation example of connecting all the logic cells with one another using the two signal lines as buses is to be described later with reference to FIG. 4.

The host 5 generates a set of signal control data and outputs it to the first logic cell 8 via the bus 7. At this time, the host 5 sets a waveform shape described in a test vector, in the waveform shape table 16 of the first logic cell 8. After that, the FPGA section 6 transfers the signal control data to the first logic cell 8 and controls the DUT 3. The host 5 receives a result of comparison between a signal value inputted from the DUT 3, which are obtained at that time, and an expected value included in the test vector from the first logic cell 8 and judges a result of execution of the test vector.

It is not necessarily required to perform analysis of a test vector and transfer of signal control data at the same time. Both of analysis of a test vector and generation of signal control data may be performed before transfer of the signal control data depending on the processing capability of the host 5. The analysis of a test vector means an operation of extracting and processing necessary signal control data and waveform shape data. To perform analysis of a test vector and transfer of signal control data at the same time means to sequentially transfer signal control data which have been analyzed while performing analysis of a test vector. That is, to perform analysis of a test vector and transfer of signal control data at the same time means to, while transferring a previous block, advance analysis of a block next to or subsequent to the block. Note that it is also possible to, after analyzing all data of the test vector in advance, transfer signal control data collectively from the host 5 to the FPGA section 6. Thereby, a load on the host 5 can be reduced.

Signal control data is transferred to the data transfer module 13 with data corresponding to a predetermined number of cycles (for example, 256 cycles) as one block. While signal control data corresponding to one block is being transferred to the data transfer module 13, the host 5 prepares next signal control data, and the FPGA section 6 performs control of the DUT 3 using blocks already transferred.

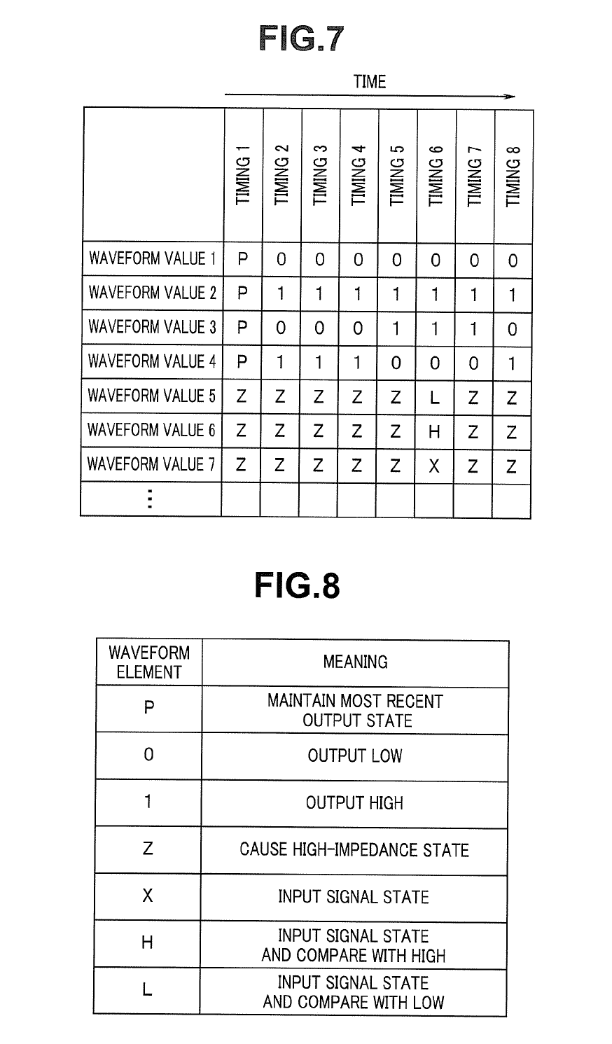

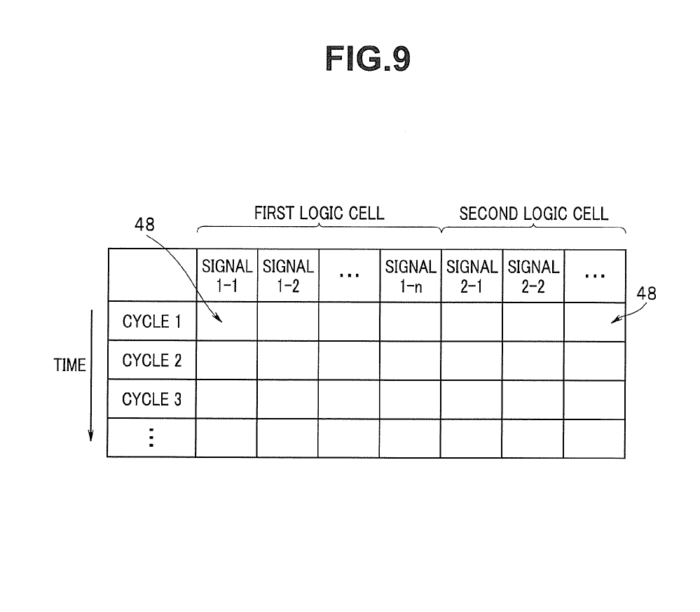

The FPGA section 6 controls the DUT 3 using definition of a waveform shape set in the FPGA section 6 in advance in accordance with signal control data transmitted from the host 5. More specifically, the FPGA section 6 controls the DUT 3 using the definition of the waveform shape (FIG. 7 to be described later) set by the host 5 in advance and the signal control data (FIG. 9 to be described later) transferred from the host 5. First, the data transfer module 13 analyzes the signal control data transmitted from the host 5. Then, the data transfer module 13 sorts the signal control data into corresponding logic cells. The signal control data is sorted into the second logic cell 9 and the third logic cell 10 via the bus 17. The signal control data is stored in a memory inside each signal control module 15.

At a stage where a predetermined amount of signal control data has been stored, each signal control module 15 synchronizes the logic cells 8, 9 and 10 using the synchronization signal lines 18 and 19. Then, when being synchronized, all the logic cells 8, 9 and 10 simultaneously start control of the DUT 3, store a result of comparison between a signal value outputted from the DUT 3 and an expected value into the memories inside the signal control modules 15 and notify it to the host 5. Note that the bus 7 and the bus 17 may be any data buses, and, for example, PCI Express 2.0x1 buses which can be generally used are used.

Here, an example of signal control in the test system 1 will be described.

FIG. 2 shows a flow of data and time at a phase where signal control data is transferred and the DUT 3 is controlled. A phase of setting definition of a waveform shape in the waveform shape table 16, and processing and the like performed for an error on the host 5 side are not shown here.

A data analyzing section of the host 5 analyzes a test vector, prepares signal control data to be transferred to the FPGA section 6, and instructs a data transferring section to start transfer. The data transferring section included in the host 5 and the FPGA section 6 transfers the signal control data from the host 5 to the FPGA section 6 via the bus 7, and sorts the signal control data into the respective logic cells 8 to 10 via the bus 17. The preparation and transfer of the signal control data are performed for each block.

After synchronizing the respective logic cells 8 to 10, the signal control modules 15 start signal processing for each cycle included in one-block data. Since the waveform shape table 16 stores information about how signal control in one cycle is performed, signal input/output sections of the signal control modules 15 perform a plurality of signal controls for the DUT 3 during one cycle on the basis of the information. At this time, a signal state is simultaneously acquired, and, if it does not correspond to an expected value in the signal control data, the FPGA section 6 causes the host 5 to generate error interrupt.

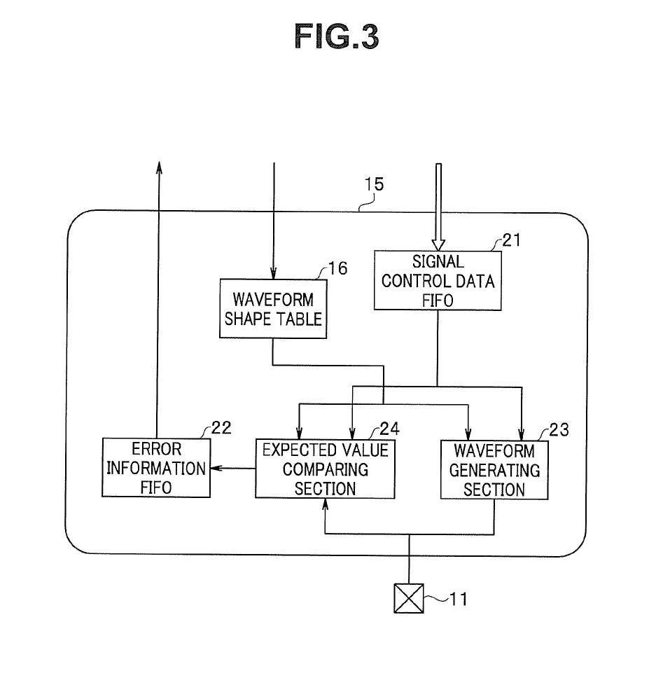

Next, a configuration of the signal control module 15 will be described. FIG. 3 is a configuration diagram of the signal control module 15.

The signal control module 15 is configured being provided with a signal control data FIFO 21 configured to store signal control data, an error information FIFO 22 configured to store a result of comparison between an output value from the DUT 3 and an expected value, a waveform generating section 23 configured to generate and output a waveform, and an expected value comparing section 24 configured to perform comparison between the output value from the DUT 3 and the expected value, in addition to the waveform shape table 16 described above in which a defined waveform shape is stored. The waveform generating section 23 and the expected value comparing section 24 are connected to the input/output terminal 11. Note that, though each of the plurality of signal control modules 15 internally has the waveform shape table 16, only one waveform shape table 16 may be held outside the plurality of signal control modules 15.

The number of waveform generating sections 23, expected value comparing sections 24 and input/output terminals 11 corresponding to the number of signals controlled by one signal control module 15 exist, and the number is equal to the number of signals included in one block. That is, if one signal control module 15 controls thirty-two input/output terminals 11, the signal control module 15 has thirty-two waveform generating sections 23 and thirty-two expected value comparing sections 24. Furthermore, though such a configuration is assumed that one logic cell has a plurality of signal control modules 15, a configuration having only one signal control module 15 is also possible.

The signal control data FIFO 21 is configured by a memory storing data corresponding to two blocks, and a block for data communication with the host 5 and a block for waveform control for the DUT 3 alternately operate as a double buffer. Signal control data transmitted from the host 5 side is stored in one buffer, and signal control data stored in the other buffer is used for signal control of the input/output terminal 11.

The waveform shape table 16 is a database for defining a waveform shape with waveform values included in signal control data as a key. The definition of the waveform shape is performed in advance by the host 5 before signal control is performed. By referring to the waveform shape table 16, it is possible to know whether a waveform value indicates an input waveform or an output waveform and what timing the waveform is to be changed and compared. Note that it is possible to update the waveform shape while signal control is being performed. At this time, it is necessary to update the waveform shape table 16 in synchronization with one cycle of the signal control.

The waveform generating section 23 operates if a waveform value indicates an output waveform, reads out a waveform shape from the waveform shape table 16 on the basis of the waveform value and outputs a signal to the input/output terminal 11.

On the other hand, the expected value comparing section 24 operates if a waveform value of signal control data indicates an input waveform and inputs a signal from the input/output terminal 11 at a timing defined in the waveform shape table 16. The expected value comparing section 24 compares the input signal with an expected value of waveform shape. The expected value is included in the signal control data. If a waveform shape corresponding to symbols (see FIGS. 7 and 8 to be described later) in the signal control data is an expected value of output value of the DUT 3, the FPGA section 6 inputs a signal from the input/output terminal 11, and judges whether the waveform corresponding to the symbols satisfies a defined condition. If the signal inputted from the input/output terminal 11 is different from the expected value, the FPGA section 6 stores information about the signal into the error information FIFO 22 and notifies the host 5 of occurrence of an input value error. After occurrence of the input value error, the host 5 can arbitrarily make a selection about whether to stop transfer of the signal control data and perform error processing and about a timing thereof.

In the case of performing signal control using a plurality of logic cells, it is necessary to perform synchronization control among the logic cells in order to uniform control timings of all signals. FIG. 4 is a configuration diagram of a circuit for realizing synchronous control among the logic cells 8, 9 and 10.

Synchronization control between two logic cells is performed with the use of two signal lines 31 and 32. The signal line 31 is an open drain type signal line pulled up by a power supply, and all the signal control modules 15 drives low. On the other hand, the signal line 32 is controlled only by a particular signal control module 15 in the first logic cell 8.

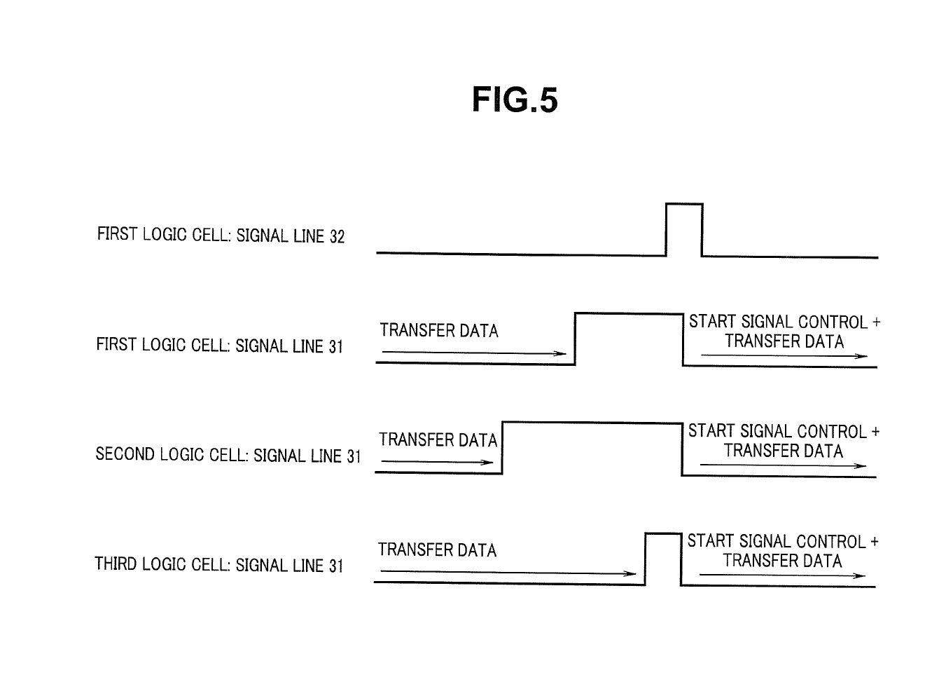

FIG. 5 is a diagram showing an example of a timing chart at the time of controlling the circuit in FIG. 4. When signal control data is not prepared in each signal control module 15, the signal line 31 is driven low. When all the signal control modules 15 are prepared, that is, all necessary signal control data is stored in a buffer of the signal control data FIFO 21, the signal line 31 is pulled up and driven high. A particular signal control module 15 in the first logic cell 8 reads the signal control data. The signal control module 15 asserts the signal line 32 from low to high at an appropriate timing in consideration of the state of the signal line 31 and the state of signal control. More specifically, the signal control module 15 asserts the signal line 32 from low to high at a timing just before the timing when the signal line 31 becomes high and signal control by one buffer of the signal control data FIFO 21 ends.

All signal control modules 15 that do not control the signal line 32 switch the buffer of the signal control data FIFO 21 by the next clock and start signal control. By switching the buffer of the signal control data FIFO 21, data transfer of signal control data resumes, the signal line 31 is driven low again, and the signal line 32 is deasserted.

Though a synchronization circuit is realized by the two signal lines 31 and 32 using an open drain in the present embodiment, a synchronization circuit using the number of signal lines corresponding to the number of logic cells plus one, depending on timing restriction or the like.

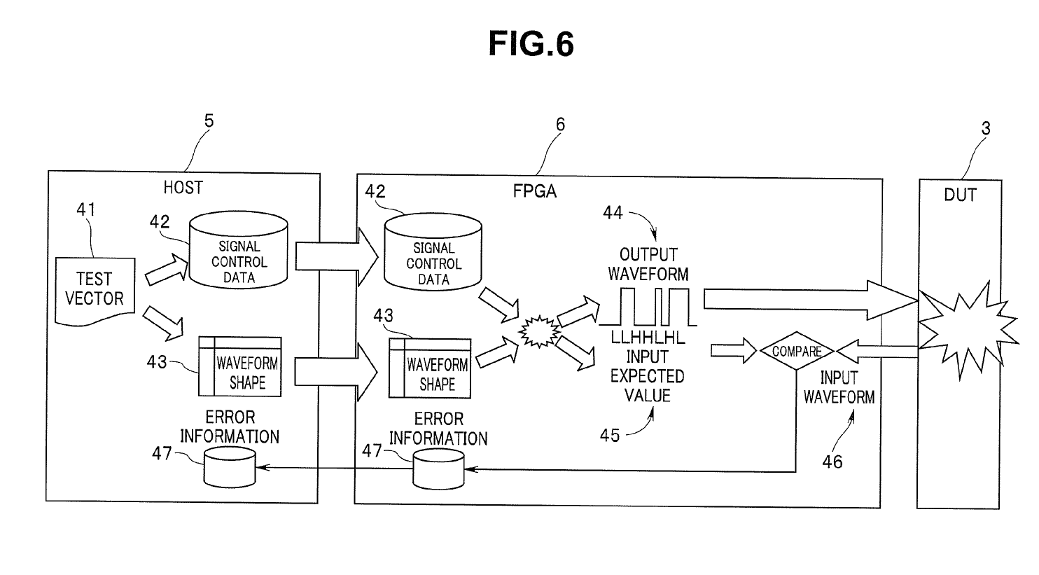

Next, data transmitted and received in the test system 1 will be described. FIG. 6 is a schematic diagram for illustrating the kinds of and transmission routes for data transmitted and received in the test system 1. FIG. 6 shows how a test vector controls the DUT 3.

The host 5 disintegrates an inputted test vector 41 into signal control data 42 and a waveform shape 43 and transfers them to the FPGA section 6. Note that the signal control data 42 includes information about a plurality of logic cells. The signal control data 42 is appropriately transferred to the signal control data FIFO 21 of each corresponding signal control module 15. The waveform shape 43 is set in the waveform shape table 16 of each signal control module 15.

The FPGA section 6 outputs an output waveform 44 to the DUT 3 on the basis of the waveform shape 43 and the signal control data 42. Otherwise, the FPGA section 6 receives an input waveform 46 (signal value) from the DUT 3 at an appropriate timing and compares the input waveform 46 with an input expected value 45 based on the waveform shape 43 and the signal control data 42. The FPGA section 6 stores a result thereof as error information 47 and notifies/transfers it to the host 5. After that, if an input value error occurs in the FPGA section 6, the host 5 performs success/failure judgment of verification by the test vector 41 by reading the error information 47 from the error information FIFO 22.

Here, an example of the waveform shape table 16 and an example of symbols which can be written as waveform elements in the waveform shape table 16 will be described.

FIG. 7 is a diagram showing an example of the waveform shape table 16, and FIG. 8 is a diagram showing an example of waveform elements in the waveform shape table 16.

In the waveform shape table 16 in FIG. 7, a horizontal axis indicates timing of the waveform elements, and a vertical axis indicates waveform values. For each waveform value, a waveform corresponding to one cycle is divided into a plurality of waveforms, and an element is defined for each of the divided waveforms. Here, one cycle is divided into eight. When signal control data with a waveform value N is given, waveform elements corresponding to the waveform value N are sequentially outputted or inputted.

The input/output terminals 11 can be set to any state of low, high and high impedance. What is obtained by adding an expected value and maintenance of an output state to the states is waveform elements shown in FIG. 8.

A waveform element “P” means to maintain the most recent output state. A waveform element “0” means to output low. A waveform element “1” means to output high. Each of waveform elements “Z”, “X”, “H” and “L” constitutes an input waveform and the waveform elements “Z”, “X”, “H” and “L” indicate “no signal”, “no expected value”, “expected value: high” and “expected value: low”, respectively.

Though “Z” and “X” are described being distinguished from each other here, the difference is only whether signal input is to be performed or not, and it does not influence operation of the DUT 3 and a test of the test vector 41. Therefore, they are not necessarily to be distinguished from each other. Note that, if “Z” and “X” are distinguished from each other, signal input without expected value comparison is performed, and it can be used for debugging of the test vector 41, operation confirmation of the DUT 3 and the like. For example, a waveform value 5 in FIG. 7 indicates that a signal state is inputted at a timing 6, and an inputted signal value is compared with low.

FIG. 9 is a diagram showing the signal control data 42 transferred from the host 5 to the FPGA section 6. The signal control data 42 is a table in which the shape of each signal in each cycle is described, and a horizontal axis and a vertical axis indicate all signals to be controlled and an order of cycles, respectively. A waveform shape 48 to be described in the table is selected from the waveform shape table 16. By creating the signal control data 42, it is possible to freely control signal waveforms corresponding to the number of cycles included in the signal control data 42, for all signals to be controlled.

Note that signals included along the horizontal axis in FIG. 9 are not necessarily required to be all signals that can be controlled by the FPGA section 6, and the table may include only signals that may change. In this case, it is only required to set a list of signals included in the signal control data 42 in advance for each logic cell.

The amount of data transferred during a unit time period can be derived from (Equation 1) below, when it is assumed that S denotes the number of signals to be controlled, W denotes the number of bits required for storing a waveform value, and F denotes the number of cycles per unit time period (frequency).

The amount of data per unit time period [bit/sec]=S[signal]×W[bit/signal]×F[cycle/sec] (Equation 1)

For example, since there are seven kinds of waveform values in the example in FIG. 7, the amount of data is 3000 [Mbit/sec] (375 MB/s) when it is assumed that W=3[bit/signal] is satisfied, the number of signals S is 100, and the frequency F is 10 MHz. This numerical value indicates the amount of data which can be transferred by one lane (unidirectionally up to 500 MB/s).

As described above, the test apparatus 2 is adapted to perform a test of the DUT 3 by controlling the input/output terminals 11 of the FPGA section 6 one-to-one connected to the respective input/output terminals 12 of the DUT 3 in a procedure described in the test vector 41 from the host 5 side.

Thereby, the test apparatus 2 can use any form that the host 5 can analyze, such as STIL, and use the test vector 41 used at other phases by an LSI tester and the like immediately as it is. Furthermore, according to the test apparatus of the present embodiment, it is possible to perform a logic test at a low cost by using a test vector developed for an LSI tester immediately as it is.

Furthermore, due to the nature of the test apparatus 2 of sequentially transferring test vectors 41 from the host 5 to the FPGA section 6, the scale of test vectors 41 which can be processed is not restricted by the performance of the FPGA section 6 and its peripheral circuits, and any test vector can be processed if it has such a scale that the host 5 can perform processing.

Furthermore, when the test apparatus 2 is compared with a general LSI tester, the cost of hardware of the test apparatus 2 can be suppressed low from the following viewpoints. By using the FPGA section 6, wiring, analog circuits and the like required to implement a substrate can be reduced to the minimum. Since test vectors 41 are sequentially transferred from the host 5, it is not necessary to store all the test vectors 41 in a memory space which can be directly accessed from the FPGA section 6, and, therefore, the FPGA section 6 does not have to have a large-scale memory. Furthermore, logics to be implemented in the FPGA section 6 may be simple ones, and it is not necessary to use an expensive FPGA section which can handle large-scale logics. Since the host 5 and the FPGA section 6 can be connected via a general-purpose bus such as a PCI Express 2.0x1 bus, it is possible to use a general inexpensive personal computer or the like as the host 5 immediately as it is. Therefore, the environment of the test apparatus 2 can be communalized with an environment for performing creation and modification of a test vector 41 and an environment to be used at the time of performing LSI verification, and it is possible to reduce the cost of a whole LSI development cycle and enhance efficiency of development work by using the same environment.

Since the input/output terminals of the FPGA section 6 and the DUT 3 are one-to-one connected in the test apparatus 2, in order to cause all the terminals to independently operate, the number of necessary input/output terminals is small. Thus, it is possible to select inexpensive logic cells, such as an FPGA section with a small number of terminals.

Furthermore, in the test apparatus 2, it is the number of the input/output terminals 11 of the FPGA section 6, the number of the signal control modules 15 of the FPGA section 6, the amount of data for signal control, transfer capability of a bus interface, and operating frequency of the DUT 3 depending on the amount of data and the transfer capability of the bus interface that influence increase in the number of signals, due to the structure of the test apparatus 2. In addition to the fact that the cost of hardware for the number of the input/output terminals 11 is low, it is easy to increase or decrease the number of the signal control modules 15 all of which can be implemented with the same structure. Therefore, by restricting the transfer ability of the bus interface or the operating frequency of the DUT 3, it is possible to control a lot of input/output terminals 11.

Furthermore, in the test apparatus 2, it is only the number of input/output terminals 12 and implementation layout that depend on the DUT 3 to be tested, in software for performing analysis and conversion of a test vector 41 on the host 5 and on the circuit substrate on the FPGA section 6 on which the signal control modules 15 are implemented. Therefore, it is not necessary to make a large-scale circuit change or a circuit change in the FPGA section 6 or reconstruct the software for each DUT 3, and it is possible to perform development to another kind of test apparatus at a low cost.

While certain embodiments have been described, these embodiments have been presented by way of example only, and are not intended to limit the scope of the inventions. Indeed, the novel apparatuses, methods and circuits described herein may be embodied in a variety of other forms; furthermore, various omissions, substitutions and changes in the form of the apparatuses, methods and circuits described herein may be made without departing from the spirit of the inventions. The accompanying claims and their equivalents are intended to cover such forms or modifications as would fall within the scope and spirit of the inventions.

What is claimed is:

1. A test apparatus comprising:
a logic cell provided with input/output terminals which are one-to-one connected to input/output terminals of a semiconductor circuit;
a host comprising a conversion section configured to analyze a test vector for performing a test of the semiconductor circuit and convert the test vector to signal control data and a waveform shape, and a judgment section configured to, by controlling the semiconductor circuit with the signal control data, analyze an expected value comparison result obtained from the logic cell to perform success/failure judgment of the test of the semiconductor circuit; and
a first bus for data transfer connecting the logic cell and the host; wherein
the logic cell comprises a first storage section configured to store the signal control data transmitted via the first bus, a second storage section configured to store the waveform shape transmitted via the first bus as a waveform shape table, a waveform generating section configured to generate an output waveform for controlling the semiconductor circuit on the basis of the signal control data and the waveform shape table and output the output waveform to the semiconductor circuit, and an expected value comparing section configured to generate an expected value on the basis of the signal control data and the waveform shape table and obtain the expected value comparison result in which a signal value inputted from the semiconductor circuit is compared with the expected value.

2. The test apparatus according to claim 1, wherein the logic cell comprises a third storage section configured to store the expected value comparison result.

3. The test apparatus according to claim 1, wherein
the logic cell is provided in a plural number,
the test apparatus further comprising:
a second bus for data transfer connecting the plural logic cells to each other; and
a synchronization signal line for synchronizing signal controls of the plural logic cells.

4. The test apparatus according to claim 3, wherein
any one of the plural logic cells comprises a data transfer module configured to sort the signal control data into the plural logic cells; and
the data transfer module sorts the signal control data into the plural logic cells via the second bus.

5. The test apparatus according to claim 1, wherein a plurality of the semiconductor circuits are connected to the logic cell.

6. A test system, comprising:
a logic cell provided with input/output terminals which are one-to-one connected to input/output terminals of a semiconductor circuit;
a host comprising a conversion section configured to analyze a test vector for performing a test of the semiconductor circuit and convert the test vector to signal control data and a waveform shape, and a judgment section configured to, by controlling the semiconductor circuit with the signal control data, analyze an expected value comparison result obtained from the logic cell to perform success/failure judgment of the test of the semiconductor circuit;
a display section configured to display a result of the success/failure judgment ; and
a first bus for data transfer connecting the logic cell and the host; wherein
the logic cell comprises a first storage section configured to store the signal control data transmitted via the first bus, a second storage section configured to store the waveform shape transmitted via the first bus as a waveform shape table, a waveform generating section configured to generate an output waveform for controlling the semiconductor circuit on the basis of the signal control data and the waveform shape table and output the output waveform to the semiconductor circuit, and an expected value comparing section configured to generate an expected value on the basis of the signal control data and the waveform shape table and obtain the expected value comparison result in which a signal value inputted from the semiconductor circuit is compared with the expected value.

7. The test system according to claim 6, wherein the logic cell comprises a third storage section configured to store the expected value comparison result.

8. The test system according to claim 6,
the logic cell is provided in a plural number,
the test system further comprising:
a second bus for data transfer connecting the plural logic cells to each other; and
a synchronization signal line for synchronizing signal controls of the plural logic cells.

9. The test system according to claim 8, wherein
any one of the plural logic cells comprises a data transfer module configured to sort the signal control data into the plural logic cells; and
the data transfer module sorts the signal control data into the plurality of logic cells via the second bus.

10. The test system according to claim 6, wherein a plurality of the semiconductor circuits are connected to the logic cell.
